(19) United States
(12) Patent Application Publication
(10) Pub. No.: US 2005/0073901 A1
(43) Pub. Date: Apr. 7, 2005

(54) Random access memory with data strobe locking circuit

(75) Inventor: Jonghee Han, Cary, NC (US)

Correspondence Address: Dicke, Billig & Czaja, PLLC;Suite 2250, Fifth Street Towers, 100 South Fifth Street, Minneapolis, MN, 55402, US

(73) Assignee: Infineon Technologies North America Corp.

(21) Appl. No.: 10/679,634

(22) Filed: Oct. 6, 2003

(51) Int. Cl. G11C 8/00

(52) U.S. Cl. 365/233

(57) ABSTRACT

A random access memory comprises a latching circuit configured to receive a first signal and provide a second signal corresponding to the first signal to latch data signals into the random access memory. The random access memory comprises a logic circuit configured to provide a first response after a predetermined number of the data signals have been latched into the random access memory by the second signal. The latching circuit is configured to receive the first response and lock the second signal to a logic level based on the first signal and the first response to prevent inadvertent latching of other data signals.

### BACKGROUND

One type of memory known in the art is double data rate synchronous dynamic random access memory (DDR SDRAM). In general, DDR SDRAM includes at least one array of memory cells. The memory cells in the array of memory cells are arranged in rows and columns, with the rows extending along an x-direction and the columns extending along a y-direction. Conductive word lines extend across the array of memory cells along the x-direction and conductive bit lines extend across the array of memory cells along the y-direction. A memory cell is located at each cross point of a word line and a bit line. Memory cells are accessed using a row address and a column address.

DDR SDRAM uses a main clock signal and a data strobe signal (DQS) for addressing the array of memory cells and for executing commands within the memory. The clock signal is used as a reference for the timing of commands such as read and write operations, including address and control signals. DQS is used as a reference to latch input data into the memory and output data into an external device.

During a write operation, two bits, four bits, or another even number of bits are collected and processed in the memory at the same time to maximize the bandwidth of the memory. DQS is controlled by a memory controller and the data bits are collected on each transition of DQS. At the first clock rising edge after the final DQS falling edge, the collection of the bits ends and the internal processing of the bits begins.

Once collection of the bits is complete, the memory controller may no longer drive the DQS signal resulting in noise on the DQS signal line. This noise, referred to as post-amble DQS noise, may oscillate around the termination voltage of the data bus. If the post-amble DQS noise occurs before internal processing of the collected data begins, the collected data can be corrupted as transitions in the post-amble DQS noise latch in undefined data in place of valid data.

### SUMMARY

One aspect of the present invention provides a random access memory. The random access memory comprises a latching circuit configured to receive a first signal and provide a second signal corresponding to the first signal to latch data signals into the random access memory. The random access memory comprises a logic circuit configured to provide a first response after a predetermined number of the data signals have been latched into the random access memory by the second signal. The latching circuit is configured to receive the first response and lock the second signal to a logic level based on the first signal and the first response to prevent inadvertent latching of other data signals.

### BRIEF DESCRIPTION OF THE DRAWINGS

Embodiments of the invention are better understood with reference to the following drawings. The elements of the drawings are not necessarily to scale relative to each other. Like reference numerals designate corresponding similar parts.

FIG. 1 is a block diagram illustrating an exemplary embodiment of a random access memory, according to the present invention.

FIG. 2 is a diagram illustrating an exemplary embodiment of a memory cell.

FIG. 3 is a schematic diagram illustrating an exemplary embodiment of a circuit for locking the DQS signal after a write operation.

FIG. 4 is a timing diagram illustrating signal timing for the locking circuit.

### DETAILED DESCRIPTION

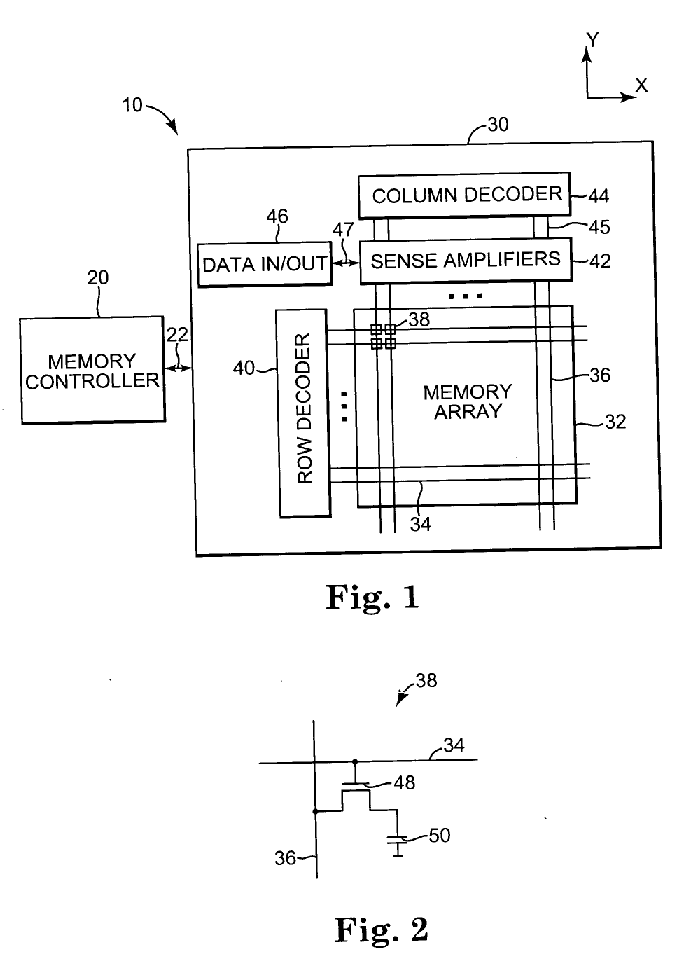

FIG. 1 is a block diagram illustrating a random access memory 10. Random access memory 10 includes a locking circuit to prevent inadvertent latching of data signals. The locking circuit is described in detail later in this application. In one embodiment, random access memory 10 is a double data rate synchronous dynamic random access memory (DDR SDRAM). The DDR SDRAM 10 includes a memory controller 20 and at least one memory bank 30. Memory bank 30 includes an array of memory cells 32, a row decoder 40, a column decoder 44, sense amplifiers 42, and data in/out circuit 46. Memory controller 20 is electrically coupled to memory bank 30, indicated at 22.

Conductive word lines 34, referred to as row select lines, extend in the x-direction across the array of memory cells 32. Conductive bit lines 36, referred to as column select lines, extend in the y-direction across the array of memory cells 32. A memory cell 38 is located at each cross point of a word line 34 and a bit line 36. Each word line 34 is electrically coupled to row decoder 40 and each bit line 36 is electrically coupled to a sense amplifier 42. The sense amplifiers 42 are electrically coupled to column decoder 44 through conductive column decoder lines 45 and to data in/out circuit 46 through data lines 47.

Data in/out circuit 46 includes a plurality of latches and data input/output (I/O) pads or pins (DQs) to transfer data between memory bank 30 and an external device. Data to be written into memory bank 30 is presented as voltages on the DQs from an external device. The voltages are translated into the appropriate signals and stored in selected memory cells 38. Data read from memory bank 30 is presented by memory bank 30 on the DQs for an external device to retrieve. Data read from selected memory cells 38 appears at the DQs once access is complete and the output is enabled. At other times, the DQs are in a high impedance state.

A bidirectional data strobe (DQS) is used as a reference to latch input data into data in/out circuit 46 from the DQs during write operations and output data into an external device through the DQs during read operations. During a write operation, DQS is driven by memory controller 20 and data bits are collected on each transition of DQS. Once collection of the bits is complete, memory controller 20 may no longer drive the DQS signal resulting in noise on the DQS signal line. To prevent the noise from latching in undefined data, a locking circuit is provided to generate an internal DQS signal (DQSi) from the DQS signal. The DQSi signal is used in place of DQS for the collection of data bits and is locked to a logic low level once collection of the data bits is complete.

Memory controller 20 controls reading data from and writing data to memory bank 30. During a read operation, memory controller 20 passes the row address of a selected memory cell or cells 38 to row decoder 40. Row decoder 40 activates the selected word line 34. As the selected word line 34 is activated, the value stored in each memory cell 38 coupled to the selected word line 34 is passed to the respective bit line 36. The value of each memory cell 38 is read by a sense amplifier 42 electrically coupled to the respective bit line 36. Memory controller 20 passes a column address of the selected memory cell or cells 38 to column decoder 44. Column decoder 44 selects which sense amplifiers 42 pass data to data in/out circuit 46 for retrieval by an external device.

During a write operation, the data to be stored in array 32 is placed in data in/out circuit 46 by an external device. DQS is provided by memory controller 20 and DQSi is generated to strobe in the data. After the data is strobed into data in/out circuit 46, DQSi is locked to a logic low level to prevent noise on the DQS signal line from latching in undefined data. Memory controller 20 passes the row address for the selected memory cell or cells 38 where the data is to be stored to row decoder 40. Row decoder 40 activates the selected word line 34. Memory controller 20 passes the column address for the selected memory cell or cells 38 where the data is to be stored to column decoder 44. Column decoder 44 selects which sense amplifiers 42 are passed the data from data in/out circuit 46. Sense amplifiers 42 write the data to the selected memory cell or cells 38 through bit lines 36.

FIG. 2 illustrates an exemplary embodiment of one memory cell 38 in the array of memory cells 32. Memory cell 38 includes a transistor 48 and a capacitor 50. The gate of transistor 48 is electrically coupled to word line 34. The drain-source path of transistor 48 is electrically coupled to bit line 36 and capacitor 50. Capacitor 50 is charged to represent either a logic 0 or a logic 1. During a read operation, word line 34 is activated to turn on transistor 48 and the value stored on capacitor 50 is read by a corresponding sense amplifier 42 through bit line 36 and transistor 48. During a write operation, word line 34 is activated to turn on transistor 48 and the value stored on capacitor 50 is written by a corresponding sense amplifier 42 through bit line 36 and transistor 48.

The read operation on memory cell 38 is a destructive read operation. After each read operation, capacitor 50 is recharged with the value that was just read. In addition, even without read operations, the charge on capacitor 50 discharges over time. To retain a stored value, memory cell 38 is refreshed periodically by reading or writing the memory cell 38. All memory cells 38 within the array of memory cells 32 are periodically refreshed to maintain their values.

In DDR SDRAM, the read and write operations are synchronized to a system clock. The system clock is supplied by a host system that includes the DDR SDRAM 10. DDR SDRAM operates from a differential clock, CK and bCK. The crossing of CK going high and bCK going low is referred to as the positive edge of CK. Commands such as read and write operations, including address and control signals, are registered at the positive edge of CK. Operations are performed on both the rising and falling edges of the system clock.

The DDR SDRAM uses a double data rate architecture to achieve high speed operation. The double data rate architecture is essentially a 2n prefetch architecture with an interface designed to transfer two data words per clock cycle at the DQs. A single read or write access for the DDR SDRAM effectively consists of a single 2n bit wide, one clock cycle data transfer at the internal memory array and two corresponding n bit wide, one half clock cycle data transfers at the DQs.

The bidirectional data strobe (DQS) is transmitted along with data for use in data capture at data in/out circuit 46. DQS is a strobe transmitted by the DDR SDRAM during read operations and by the memory controller, such as memory controller 20, during write operations. DQS is edge aligned with data for read operations and center aligned with data for write operations. Input and output data is registered on both edges of DQS.

During a write operation, DQS is controlled by memory controller 20. Once the write operation is complete, memory controller 20 no longer controls the DQS signal resulting in noise on the DQS signal. This noise, referred to as post-amble DQS noise, can oscillate around the termination voltage of the data bus. If this post-amble DQS noise occurs before internal processing of the collected data begins, the collected data can be corrupted as transitions in the post-amble DQS noise can latch in undefined data in place of valid data.

Read and write accesses to the DDR SDRAM are burst oriented. Accesses start at a selected location and continue for a programmed number of locations in a programmed sequence. Accesses begin with the registration of an active command, which is followed by a read or write command. The address bits registered coincident with the active command are used to select the bank and row to be accessed. The address bits registered coincident with the read or write command are used to select the bank and the starting column location for the burst access.

The DDR SDRAM in the preceding description is referred to as DDR-I SDRAM for being the first generation of DDR SDRAM. The next generation of DDR SDRAM, DDR-II SDRAM has the same features as DDR-I SDRAM except that the data rate is doubled. The DDR-II SDRAM architecture is essentially a 4n prefetch architecture with an interface designed to transfer four data words per clock cycle at the DQs. A single read or write access for the DDR-II SDRAM effectively consists of a single 4n bit wide, one clock cycle data transfer at the internal memory array and four corresponding n bit wide, one quarter clock cycle data transfers at the DQs. In one embodiment, DDR SDRAM 10 is a DDR-II SDRAM.

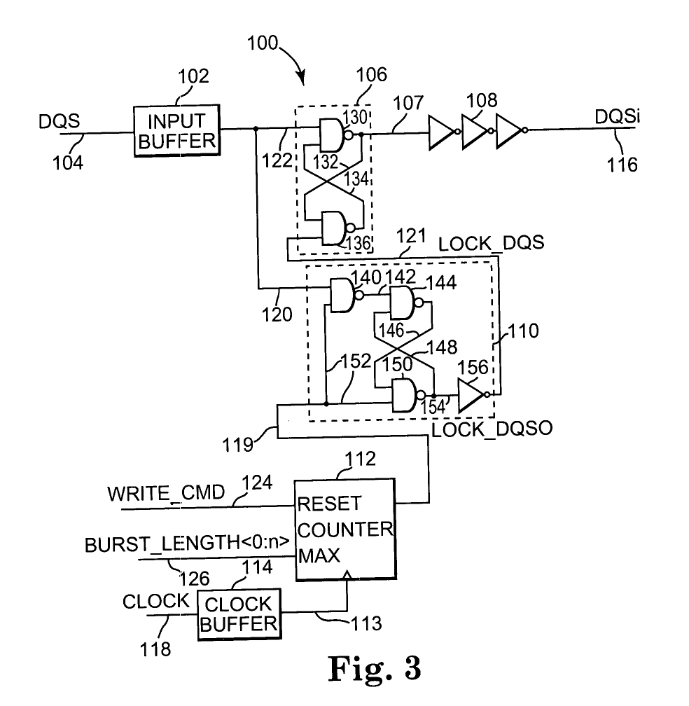

FIG. 3 is a schematic diagram illustrating an exemplary embodiment of a DQS locking circuit 100 that is a part of data in/out circuit 46. Locking circuit 100 includes input buffer 102, DQS latch 106, inverters 108, DQS preliminary latch 110, counter 112, and clock buffer 114. Locking circuit 100 receives input signals DQS 104, write command 124, burst length 126, and clock 118, and outputs signal DQSi 116.

DQS 104 is input to input buffer 102. Input buffer 102 is electrically coupled to DQS latch 106 through signal path 122. DQS latch 106 is electrically coupled to invertors 108 through signal path 107. Inverters 108 provide output signal DQSi 116 used for latching in the burst data. In one embodiment, inverters 108 are included in DQS latch 106. Input buffer 102 is also electrically coupled to DQS preliminary latch 110 through signal path 120. Preliminary latch 110 is electrically coupled to counter 112 through signal path 119. DQS preliminary latch 110 is also electrically coupled to DQS latch 106 through signal path 121. Clock 118 is input to clock buffer 114. Clock buffer 114 is electrically coupled to counter 112 through signal path 113. Write command 124 and burst length 126 are inputs to counter 112. In one embodiment, counter 112 is replaced by a shift register or shifter.

DQS latch 106 is a NAND gate latch. DQS latch 106 includes NAND gates 130 and 136. The output of NAND gate 130 is electrically coupled to an input of NAND gate 136 through signal path 132. The output of NAND gate 130 is also electrically coupled to signal path 107. The output of NAND gate 136 is electrically coupled to an input of NAND gate 130 through signal path 134. Signal path 122 is electrically coupled to an input of NAND gate 130. Signal path 121 is electrically coupled to an input of NAND gate 136.

DQS preliminary latch 110 is a modified NAND gate latch. DQS preliminary latch 110 includes NAND gates 140, 144, and 150, and inverter 156. The output of NAND gate 140 is electrically coupled to an input of NAND gate 144 through signal path 142. An input of NAND gate 140 is electrically coupled to an input of NAND gate 150 through signal path 152. The output of NAND gate 144 is electrically coupled to an input of NAND gate 150 through signal path 146. The output of NAND gate 150 is electrically coupled to an input of NAND gate 144 through signal path 148. The output of NAND gate 150 is electrically coupled to the input of inverter 156 through signal path 154. In one embodiment, inverter 156 is external to DQS preliminary latch 110. Signal path 120 is electrically coupled to an input of NAND gate 140. Signal path 119 is electrically coupled to signal path 152. Signal path 121 is electrically coupled to the output of inverter 156.

The output of counter 112 on signal path 119 is a flag signal LOCK_DQS0. LOCK_DQS0 is logic high when the count of counter 112 equals the input burst length 126. The output of DQS preliminary latch 110 on signal path 121 is a flag signal LOCK_DQS. LOCK_DQS transitions to logic high when LOCK_DQS0 is logic high and the signal on signal path 120 is logic high.

The output of DQS preliminary latch 110, LOCK_DQS, remains logic low while DQS preliminary latch 110 input LOCK_DQS0 remains logic low. Once input LOCK_DQS0 transitions to logic high and the signal on signal path 120 transitions to logic high, output LOCK_DQS on signal path 121 transitions to logic high.

The output of DQS latch 106 on signal path 107 equals the inverse of the signal on signal path 122 as long as LOCK_DQS is logic low. Once LOCK_DQS transitions to logic high and the signal on signal path 122 transitions to logic low, the output of DQS latch 106 on signal path 107 is set to logic high. The signal on signal path 107 is inverted by inverters 108 and output to DQSi 116.

Counter 112 is reset by the initialization of a write command 124. For each clock pulse 118 received by counter 112, the count of counter 112 is incremented. Once the count of counter 112 reaches the specified burst length 126, counter 112 sets LOCK_DQS0 logic high. In one embodiment, a shift register or shifter is used in place of counter 112. The shifter includes the same inputs and output as counter 112 and a series of latches. Instead of counting clock pulses, however, the shifter shifts a bit through one latch of the shifter for each clock pulse up to the selected burst length 126.

Locking circuit 100 is one representation of the concept of using a two stage locking scheme to prevent post-amble DQS noise from corrupting data during write operations. The actual circuit can vary from the circuit illustrated without departing from the scope of this invention. For example, different types of latches can be substituted for NAND latches 106 and 110.

During a write operation, write command 124 is used to reset counter 112, which is used to count the data bursts to determine when all data to be written to DDR SDRAM 10 has been received and latched in. Counter 112 counts up to the programmed burst length and then sets output flag signal LOCK_DQS0 to logic high. LOCK_DQS0 is passed to DQS preliminary latch 110. With the signal on signal path 120 at a logic high or when the signal on signal path 120 transitions to a logic high, DQS preliminary latch 110 output flag LOCK_DQS transitions to logic high. LOCK_DQS is passed to DQS latch 106. Once the signal on signal path 122 transitions to logic low, DQSi 116 is locked logic low. Therefore, any post-amble DQS noise is blocked from being transmitted through to DQSi, eliminating the possibility of write data being corrupted.

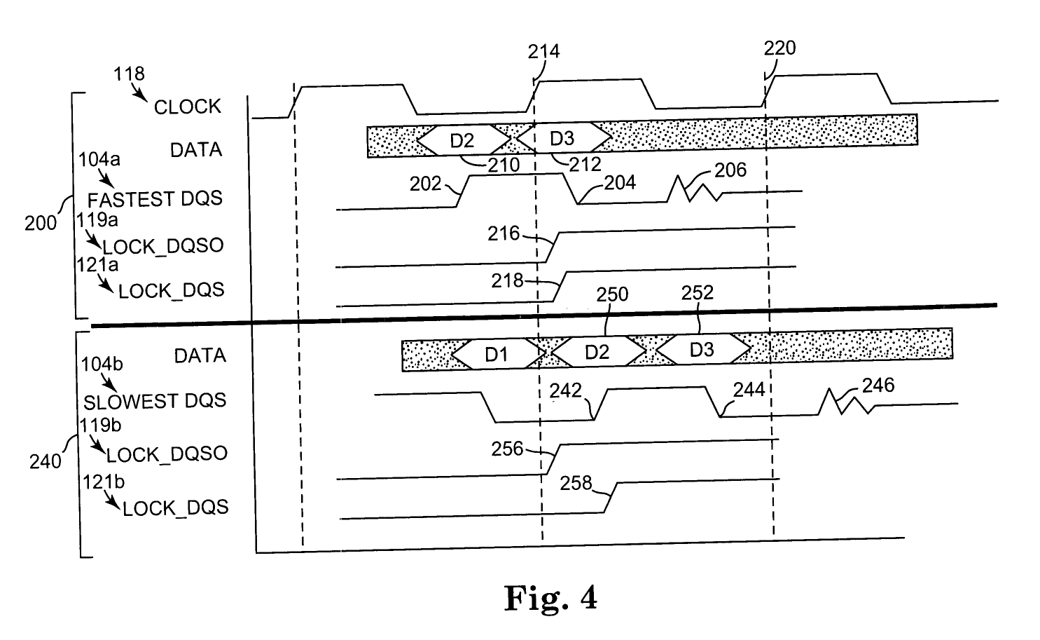

FIG. 4 is a timing diagram illustrating the operation of locking circuit 100. Section 200 illustrates the timing of locking circuit 100 for the fastest DQS signal 104a and section 240 illustrates the timing of locking circuit 100 for the slowest DQS signal 104b. The fastest DQS signal 104a and the slowest DQS signal 104b represent the limits of where the DQS signal transitions fall with respect to clock signal 118. The same clock signal 118 is used for both sections 200 and 240. The timing diagram illustrates the timing of signals from just before counter 112 counts the last rising edge of the clock pulse resulting in the count equaling the burst length 126. In this embodiment, the burst length is four.

In section 200, data D2 at 210 and D3 at 212 are latched in on the rising edge at 202 and the falling edge at 204 of the fastest DQS 104a respectively. The rising edge of the clock at 214 causes LOCK_DQS0 119a to transition to logic high at 216 as the count of counter 112 reaches the burst length 126. Since DQS 104a is also at a logic high level at 214, LOCK_DQS 121a transitions to logic high at 218 after LOCK_DQS0 119a transitions to logic high at 216. Once DQS 104a transitions to logic low at 204, DQSi (not shown) is locked at a logic low level and the post-amble DSQ noise at 206 is blocked from latching in undefined data. Internal processing of the collected data begins at 220.

In section 240, data D2 at 250 and D3 at 252 are latched in on the rising edge at 242 and the falling edge at 244 of the slowest DQS 104b respectively. The rising edge of clock 118 at 214 causes LOCK_DQS0 119b to transition to logic high at 256 as the count of counter 112 has reached the burst length 126. LOCK_DQS 121b transitions to logic high at 258 after DQS 104b transitions to logic high at 242. Once DQS 104b transitions to logic low at 244, DQSi (not shown) is locked at a logic low level and the post-amble DQS noise 246 is blocked from latching in undefined data. Internal processing of the collected data begins at 220.

The two stage locking scheme described herein prevents post-amble DQS noise from corrupting input data during write operations. The DQSi signal generated from DQS is locked at a logic low level after all input data has been latched in. Valid data is not lost due to post-amble DQS noise latching in undefined data in place of valid data.

1. A random access memory, comprising:
a latching circuit configured to receive a first signal and provide a second signal corresponding to the first signal to latch data signals into the random access memory; and
a logic circuit configured to provide a first response after a predetermined number of the data signals have been latched into the random access memory by the second signal, wherein the latching circuit is configured to receive the first response and lock the second signal to a logic level based on the first signal and the first response to prevent inadvertent latching of other data signals.

2. The random access memory of claim 1, wherein the latching circuit comprises:
a first latch electrically coupled to the logic circuit; and
a second latch electrically coupled to the first latch.

3. The random access memory of claim 1, wherein the latching circuit comprises:
a first latch configured to receive the first response and provide a second response based on the first response and the first signal; and
a second latch configured to receive the second response and lock the second signal to the logic level based on the first signal and the second response.

4. The random access memory of claim 1, wherein the logic circuit comprises a counter configured to count clock cycles that correspond to the data signals latched into the random access memory.

5. The random access memory of claim 1, wherein the logic circuit comprises a shift register configured to shift in response to clock cycles that correspond to the data signals latched into the random access memory.

6. The random access memory of claim 1, wherein the logic circuit is configured to respond to positive edges of a clock signal after a write command to determine the predetermined number of the data signals latched into the random access memory.

7. The random access memory of claim 1, wherein the logic circuit comprises a counter configured to be reset by a write command signal.

8. The random access memory of claim 1, wherein the logic circuit comprises a shift register configured to be reset by a write command signal.

9. The random access memory of claim 1, wherein the logic circuit is configured to receive a write command signal that resets the logic circuit.

10. The random access memory of claim 1, wherein the logic circuit is configured to receive burst length infomation that sets the predetermined number of the data signals to a burst length value.

11. The random access memory of claim 1, wherein the logic level is a low logic level.

12. A random access memory, comprising:
a logic circuit configured to receive a clock signal and provide a first response after a predetermined number of clock edges have been received from the clock signal;
a first latch circuit configured to receive the first response and a first signal and provide a second response based on the first response and the first signal; and
a second latch circuit configured to receive the second response and the first signal and provide a corresponding second signal, wherein the second latch circuit is configured to lock the second signal to a logic level based on the second response and the first signal.

13. The random access memory of claim 12, wherein the logic circuit comprises a counter configured to receive burst length information that comprises the predetermined number of clock edges and receive a write command signal that is an indication to start counting the clock edges.

14. The random access memory of claim 12, wherein the logic circuit comprises a shift register configured to receive burst length information that comprises the predetermined number of clock edges and receive a write command signal that is an indication to start shifting the shift register in response to the clock edges.

15. The random access memory of claim 12, wherein the random access memory is a double data rate synchronous dynamic random access memory.

16. The random access memory of claim 12, wherein the random access memory is a DDR-I SDRAM.

17. The random access memory of claim 12, wherein the random access memory is a DDR-II SDRAM.

18. A random access memory comprising:
a locking circuit that receives a first data strobe and generates a second data strobe from the first data strobe, wherein the second data strobe latches input data during a write operation and is locked at a logic level after the input data is latched.

19. The random access memory of claim 18, wherein the locking circuit comprises a counter configured to start counting in response to a write command signal and count bursts of input data up to a burst length to determine that the input data is latched.

20. The random access memory of claim 18, wherein the locking circuit comprises a shift register configured to start shifting in response to a write command signal and shift up to a burst length to determine that the input data is latched.

21. The random access memory of claim 18, wherein the memory comprises a DDR-I SDRAM.

22. The random access memory of claim 18, wherein the memory comprises a DDR-II SDRAM.

23. A random access memory comprising:
means for receiving a first data strobe and generating a second data strobe from the first data strobe, wherein the second data strobe latches in first signals during a write operation; and
means for preventing the second data strobe from latching in second signals after latching in the first signals.

24. The random access memory of claim 23, wherein the means for preventing comprises:
means for indicating the first signals are latched, wherein the means for indicating provides an indication; and
means for locking the second data strobe to a logic level based on the indication.

25. The random access memory of claim 24, wherein the means for locking comprises:
means for latching a first output based on the first data strobe and the indication; and
means for latching a second output based on the first data strobe and the first output, wherein the means for latching a second output locks the second data strobe to the logic level.

26. A method for rejecting noise in a random access memory, comprising:
indicating that a burst of data signals are received;
setting a first flag based on the indication;
setting a second flag based on the first flag; and
locking a first data strobe signal to a logic level based on the second flag.

27. The method of claim 26, wherein indicating that a burst of data signals are received comprises counting clock cycles up to a set value.

28. The method of claim 27, wherein the burst length is one of 2, 4, 8, 16, and 32.

29. The method of claim 26, wherein indicating that a burst of data signals are received comprises shifting a shift register for each data signal in the burst of data signals up to a set value.

30. The method of claim 29, wherein the burst length is one of 2, 4, 8, 16, and 32.

31. The method of claim 26, wherein setting a first flag comprises:
receiving a second data strobe signal;
receiving the indication; and
latching in the first flag based on a state of the second data strobe signal.

32. The method of claim 26, wherein setting a second flag comprises:
receiving a second data strobe signal;
receiving the first flag; and
latching in the second flag based on a state of the second data strobe signal.
